(19) United States
(12) Patent Application Publication
(10) Pub. No.: US 2024/0120338 A1
(43) Pub. Date: Apr. 11, 2024

(54) SEMICONDUCTOR DEVICE STRUCTURE AND METHOD FOR FORMING THE SAME

(71) Applicant: TAIWAN SEMICONDUCTOR MANUFACTURING COMPANY, LTD., Hsinchu (TW)

(72) Inventors: Ta-Chun LIN, Hsinchu (TW); Ming-Che CHEN, Hsinchu (TW); Yu-Hsuan LU, Kaohsiung (TW); Chih-Hao CHANG, Hsinchu (TW)

(21) Appl. No.: 18/110,330

(22) Filed: Feb. 15, 2023

Related U.S. Application Data
(60) Provisional application No. 63/414,539, filed on Oct. 9, 2022.

(51) Int. Cl. H01L 27/092; H01L 21/8238

(52) U.S. Cl. CPC H01L 27/092; H01L 21/823871; H01L 21/823878

(57) ABSTRACT

A semiconductor device structure is provided. The semiconductor device has a first dielectric wall between an n-type source/drain region and a p-type source/drain region to physically and electrically isolate the n-type source/drain region and the p-type source/drain region from each other. A second dielectric wall is formed between a first channel region connected to the n-type source/drain region and a second channel region connected to the p-type source/drain region. A contact is formed to physically and electrically connect the n-type source/drain region with the p-type source/drain region, wherein the contact extends over the first dielectric wall. The first electric wall has a gradually decreasing width W₅ towards a tip of the dielectric wall from a top contact position between the first dielectric wall and either the n-type source/drain region or the p-type source/drain region.

### CROSS-REFERENCE TO RELATED APPLICATIONS

This application claims priority to U.S. Provisional Application Ser. No. 63/414,539 filed Oct. 9, 2022, which is incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate. The various material layers can also be patterned using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an exemplary forksheet transistor device in accordance with some embodiments.

FIGS. 2-4, 5A-5B, 6A-6B, 7A-7B, 8A-8B, 9A-9B, 10A-10B, 11A-11B, 12A-12B, 13A-13B, 14A-14B, 15A-15B, 16A-16B, and 17A-17B are cross-sectional views of intermediate stages in the manufacture of a forksheet device in accordance with some embodiments.

FIGS. 18A-18B, 19A-19B, 20A-20B, 21A-21B, 22A-22B, 23A-23B, 24A-24B, 25A-25B, 26A-26B, 27A-27B, 28A-28B, 29A-29B, and 30 are cross-sectional views of intermediate stages in the manufacture of a forksheet device in accordance with some embodiments.

FIGS. 31-32 are cross-sectional views of intermediate stages in the manufacture of a forksheet FET device in accordance with some embodiments.

FIGS. 33-34 are cross-sectional views of intermediate stages in the manufacture of a forksheet FET device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Source/drain region(s) may refer to a source or a drain, individually or collectively dependent upon the context.

Embodiments will be described with respect to a specific context, namely, a forksheet transistor device and a method of forming the same. A forksheet transistor device integrates an n-type MOS or FET (NMOS or NFET) and a p-type MOS or FET (PMOS or PFET) in the same structure and uses a bifurcate gate structure to control each nanosheet structure. A dielectric wall is introduced to achieve physical and electric isolation between neighboring NFET and PFET. The dielectric wall reduces the distance between the neighboring NFET and PFET to meet the required scalability for high device performance. Various embodiments discussed herein allow for forming the forksheet transistor device, such that the resistance between the contact structures connecting the sources/drains is reduced. Various embodiments presented herein are discussed in the context of forksheet transistor device.

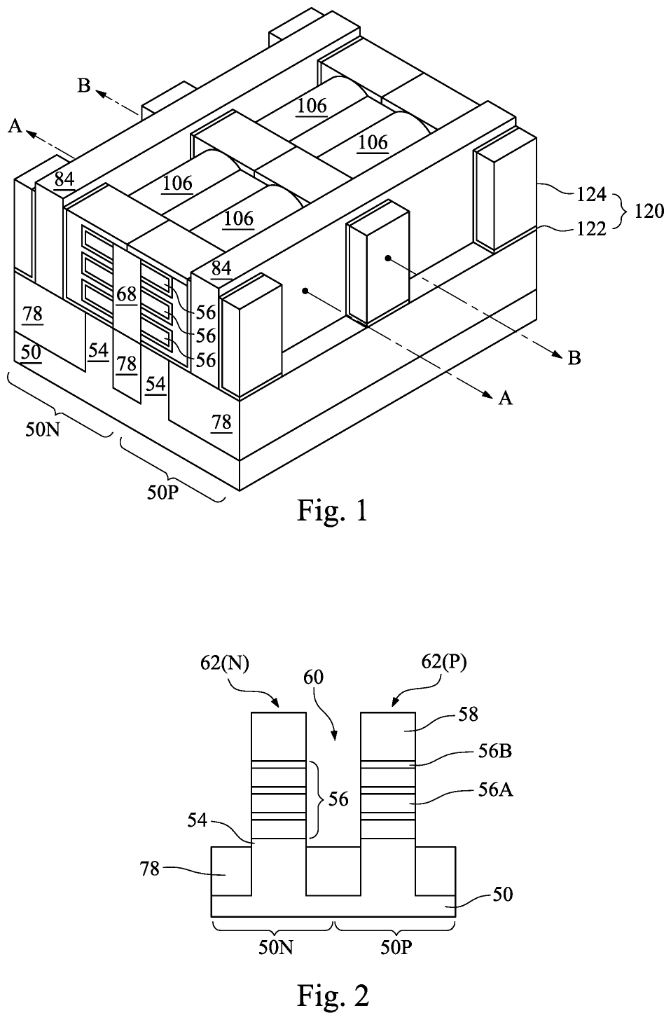

FIG. 1 provides an exemplary forksheet field effect transistor (FET) device according to some embodiments. FIG. 1 is a cutaway three-dimensional view, where some features of the forksheet FET are omitted for illustration clarity. The forksheet FET includes nanostructures 56 over portions of the substrate 50, for example, semiconductor fins 54 extending from the substrate 50. The nanostructures 56 include semiconductor layers functioning as channel regions for the forksheet FET. Isolation regions 78 such as shallow trench isolation (STI) regions are disposed over the substrate 50 adjacent to the semiconductor fins 54. Although the isolation regions 78 are described/illustrated as being separate from the substrate 50, as used herein, the term “substrate” may refer to the substrate 50 alone or a combination of the substrate 50 and the isolation regions 78. Additionally, although the semiconductor fins 54 are illustrated as single, continuous materials with the substrate 50, the semiconductor tins 54 and/or the substrate 50 may include a single material or multiple materials. In this context, the semiconductor fin s 54 refer to the portion of the substrate 50 extending above and from between the neighboring isolation regions 78.

Gate structures 120 are formed to wrap around the nanostructures (or nanosheets) 56 over the fins 54. The gate structures 120 may include gate dielectrics 122 and gate electrodes 124. The gate dielectrics 122 are formed along top surfaces, sidewalls, and bottom surfaces of the nanostructures 56 and may extend along sidewalls and/or over top surfaces of the semiconductor fins 54. The gate electrodes 124 are on the gate dielectrics 122. Epitaxial source/drain regions 106 are disposed on opposite sides of the gate structures 120. In embodiments where multiple transistors are formed, the epitaxial source/drain regions 106 may be shared between various transistors. One or more interlayer dielectric (ILD) laver(s) (discussed in greater detail below) are over the epitaxial source/drain regions 106 and/or the gate structures 120, through which contacts (discussed in greater detail below) to the epitaxial source/drain regions 106 and the gate electrodes 124 are formed.

In the illustrated embodiment, the substrate 50 includes a n-type region 50N and a p-type region 50P. The n-type: region 50N includes n-type devices, for example, NMOS transistors such as n-type nano-FETs. The p-type region 50P includes p-type devices, for example, PMOS transistors such as p-type nano-FETs. In forksheet FETs, both n-type devices and p-type devices are integrated in the same forksheet structure. A dielectric wall 68 separates the semiconductor fin 54, the nanostructures 56, and the epitaxial source/drain regions 106 of an n-type device from the semiconductor fin 54, the nanostructures 56, and the epitaxial source/drain regions 106 of a p-type device. The gate structures 120 extend along three sides of each nanostructure 56. Forksheet FETs allow n-type; devices and p-type devices to be formed close to each other and allow the gate structures 120 for the devices to be physically and electrically coupled to one another; thereby reducing the amount of gate contacts used in a CMOS process. Dielectric fins 84 are formed over the isolation regions 78 at cell boundaries to separate adjacent forksheet FETs.

FIG. 1 further illustrates reference cross-sections that are used in later figures. Cross-section A-A is perpendicular to a longitudinal axis of a nanostructure 56 and in a direction, for example, of current flow between the epitaxial source/′drain regions 106. Cross-section B-B is parallel to cross-section A-A and is along a longitudinal axis of a gate structure 120.

FIGS. 2 through 17A-B are cross-sectional views of intermediate stages in the manufacturing of forksheet FETs in accordance with some embodiment. In FIGS. 2 through 17A-B, figures ending with an “A” designation are illustrated along the reference cross-section A-A illustrated in FIG. 1 and figures ending with a “B” designation are illustrated along the reference cross-section B-B illustrated in FIG. 1.

In FIG. 2, a substrate 50 is provided for forming forksheet FETs. The substrate 50 may be a semiconductor substrate, such as a bulk semiconductor, a semiconductor-on-insulator (SOT) substrate, or the like, which may be doped (e.g., with a p-type or a n-type dopant) or undoped. The substrate 50 may be a wafer, for example, a silicon wafer. In the illustrated embodiment, the substrate 50 may be a SOI substrate including a semiconductor layer formed on an insulator layer, for example, a buried oxide (BOX) layer, a silicon oxide layer, or the like. The insulator layer may be provided on a substrate core, which is typically a silicon or glass substrate. Other substrates, such as a multi-layered or gradient substrate may also be used. In some embodiments, the semiconductor material of the substrate 50 (e.g., the semiconductor layer) may include silicon, germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 may further include integrated circuit devices (not shown). As one of ordinary skill in the art will recognize, a wide variety of integrated circuit devices such as transistors, diodes, capacitors, resistors, the like, or combinations thereof may be formed in and/or on the substrate 50 to generate the structural and functional requirements of the design for the resulting FETs. The integrated circuit devices may be formed using any suitable methods. In some embodiments, the substrate 50 may comprise a region for forming n-type devices, for example, NMOS transistors such as n-type FinFETs, or p-type devices, for example, PMOS transistors such as p-type FinFETs, may be formed in a similar manner.

To form a forksheet transistor device, a multi-layer stack (to be patterned into the nanostructures 56) including alternate first semiconductor layers 56A and second semiconductor layers 56B is formed over the substrate 50. In the illustrated embodiment, the multi-layer stack 56 includes three first semiconductor layers 56A and three second semiconductor layers 56B. It is appreciated that the multi-layer stack 56 may include any number of the first semiconductor layers 56A and the second semiconductors 56B alternately formed on the substrate 50. For example, the multi-layer stack may include from about three to about eight layers of each of the semiconductor layers 56A and 56B.

In one embodiment, the second semiconductor layers 56B may be used for forming channel regions for the FETs in both the n-type region 50N and the p-type region 50P. The first semiconductor layers 56A may serve as sacrificial layers which will be removed in subsequent processes to expose the top surfaces and the bottom surfaces of the second semiconductor layers 56B in both the n- and p-type regions 50N and 50P. Materials suitable for forming the second semiconductor layers 56B may include silicon, while materials for forming the first semiconductor layers 56A may be selected from the materials having high etching selectivity with respect to the material for forming the second semiconductor layers. For example, the second semiconductor layers 56B may be made of silicon germanium.

In another embodiment, the first semiconductor layers 56A may be used for forming channel regions in one region, for example, the p-type region 50P, and the second semiconductor layers 56B may be used for forming channel regions in the other regions, for example, the n-type regions 50N. Suitable materials of the first semiconductor layers 56A used for forming channel regions in the p-type region 50P may include silicon germanium such as SixGe₁₋ₓ with x in the range of 0 to 1, pure or substantially pure germanium, a III-V compound semiconductor, a II-VI compound semiconductor or the like. The second semiconductor layers 56B for forming the channel regions in the n-type regions 50N may be made of materials including silicon, silicon carbide, a III-V compound semiconductor, a II-VI semiconductor, or the like. A high etching selectivity is an important factor while selecting the appropriate materials for forming the first and second semiconductor layers, such that one of the semiconductor layers and may be removed without removing the other of the first and second semiconductor layers 56A and 56B.

Each of the first and second semiconductor layers and may be grown by process such as vapor phase epitaxy (VPE) or molecular beam epitaxy (MBE), deposited by a process such as chemical vapor deposition (CVD) or atomic layer deposition (ALD), or the like. Each of the first and second semiconductor layers and may be formed with a thickness of about 5 nm to about 30 nm. In one embodiment, each of one of the first and second semiconductor layers and may be formed with a thickness thicker than each of the other. For example, each of the first and second semiconductor layers used for forming the channel regions may be formed thicker than each of the other serving as sacrificial layers. The relative thickness of the first and second semiconductor layers may be determined based on the desired channel heights and the channel wok function requirements of the resulting FET.

Further referring to FIG. 2, the substrate 50 and the multi-layer stack 56 over the substrate 50 are etched to form a fin structure 62N in a region predetermined as the n-type region and a fin structure 62N in a region predetermined as the p-type region 50P. Each of the fin structures 62N and 62P includes a semiconductor fin 54 and a fin structure 56 formed over the semiconductor fin 54, and a trench 60 between the fin structures 62N and 62P. The semiconductor fins 54 are semiconductor strips formed in the substrate 50, while the fin structures 62 including the patterned alternate first and second semiconductor layers 56A and 56B extending over the corresponding semiconductor fins 54. In the embodiment where the substrate 50 is an SOI substrate, the semiconductor fins 54 include the remaining portions of a semiconductor layer at the top of the substrate 50. The nanostructures 56 include the patterned first and second semiconductor layers 56A and 56B. The etching process may include reactive ion etch (RIE), neutral beam etch (NBE), or a combination thereof, performed using a mask 58 over the nanostructures 56 as shown in FIG. 2. The mask 58 may be a single-layer mask or a multilayer mask with layers of different etch selectivity.

The fin structures 62N and 62P may have same width in the range of about 5 nm to about 20 nm. In some embodiments, the fin structure 62N may be wider or narrower than the fin structure 62P. The adjacent fin structures 62N and 62P are formed in pair. The fin structure 62N in each pair is used to for m an n-type device, while the fin structure 62P is used to form a p-type device. The fin structures 62N and 62P will be separated by the trench 60 as shown in FIG. 2. A dielectric wall will be formed to fill the trench 60 which will be discussed in detail hereinafter to provide isolation between the fin structures 62N and 62P. The trench 60 may have a width (distance between fin structures 62N and 60P) ranging from about 6 nm to about 30 nm. Compared to the trenches 60 formed between the fin structures 62N and 62P within the same pair, trenches may be formed between outside of the fin structures 62N and 62P within the same pair with a larger width, for example, ranging from about 22 nm to about 46 nm.

Although it is not shown in the figures, a liner may be formed over the mask 58, the fin structures 62, and the substrate 50, and a dielectric layer may be formed over the liner layer. As shown in FIG. 2, isolation regions 78, for example, shallow trench isolations (STI) are formed to fill a portion of the trenches 60. In the illustrated embodiment, the isolation regions 78 are recessed from the top surfaces of the semiconductor fins 54, such that the nanostructures 56 protrude above the isolation regions 78. The isolation regions 78 may be recessed using an oxide removal etchant such as dilute hydrofluoric (dHF) acid. Time etching may also be used to stop the etching process after the isolation regions 78 reach a predetermined height. The isolation regions 78 isolate the adjacent semiconductors fins 54. In some embodiments, the top surfaces of the isolation regions 78 may be coplanar with or extend above the top surfaces of the semiconductor fins 54. Further, in the embodiment as shown in FIG. 2, the isolation regions 78 have flat top surfaces. In some embodiments, the isolation regions 78 may be formed with convex or concave.

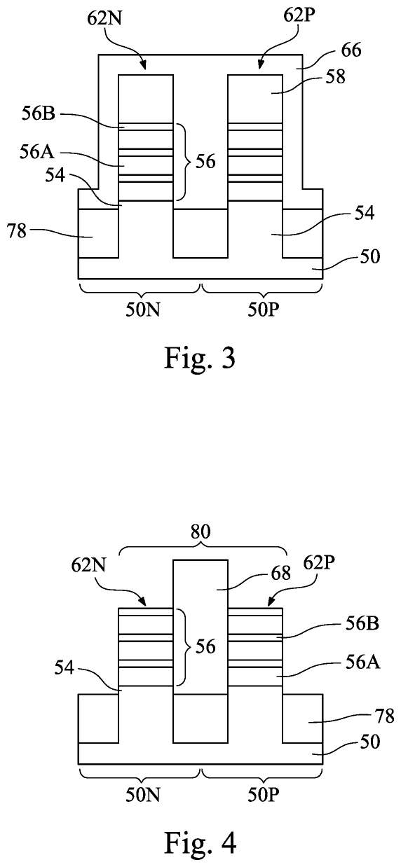

Referring to FIG. 3, a dielectric layer 66 is formed to fill the trench 60 between the fin structures 62N and 62P. In the illustrated embodiments, the trench 60 between the pair of the fin structures 60N and 62P has a narrower pitch than those of openings or trenches outside of the pair of the fin structures 62N and 62P. Therefore, the trench 60 may be completely filled or overfilled with the dielectric layer 66, while the recessed portions outside of the pair of fin structures 62N and 62P, that is, trenches formed between neighboring pairs are not completely filled. In FIG. 3, the dielectric layer 66 may be formed with low k-value dielectric materials such as silicon nitride by ALD or CVD.

In FIG. 4, the dielectric layer 66 is etched back using the sacrificial layer 58 as a hard mask to form the dielectric wall 68 between the fin structures 62N and 62P, while the dielectric layer 66 outside each pair of the fin structures 62N and 62P is removed to expose the isolation regions 78. The sacrificial layer 58 is then removed to expose the nanostructures 56. In one embodiment, the dielectric layer 66 may be formed from materials selected from SiO₂, SiN, SiCN, SiCON, SiCO, AlO, HfO, or other high k-value material with k≥7, and may be composite with multi-layers of these materials, for example. In the embodiment as shown in FIG. 4, the second semiconductor layers 56B of the nanostructures 56 is exposed after the sacrificial layer 58 is removed. Although FIG. 4 shows only one n-type region 50N and one p-type region 50P, the substrate 50 may include any desired quantity of such regions. The fin structures 62N and 62P are formed in an n-type region 50N and a p-type region (50P), respectively. The dielectric wall 68 between the fin structures 62N and 62P is disposed at boundaries between the n-type region 50N and a p-type region 50P.

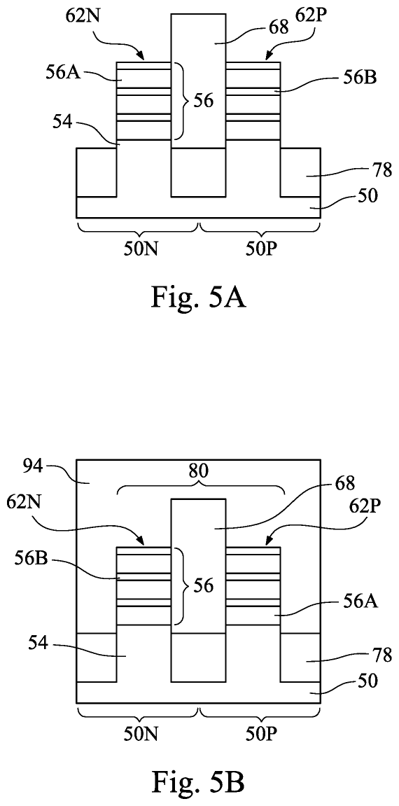

A stack of dummy gates 94 is formed to periodically cover the exposed isolation regions 78, the pair of fin structures 62P and 62N, and the dielectric wall 68 between the fin structures 62N and 62P as shown in FIG. 5B. FIG. 5A shows the isolation regions 78, the pair of fin structures 62N and 62P, and dielectric wall 68 exposed in the intervals between the adjacent dummy gates 94. The dummy gates 94 may be formed by forming a dummy gate layer and patterning the dummy gate layer. The dummy gate layer may be deposited and then planarized, such as by a CMP. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physic& vapor deposition (PVD), CVD, sputter deposition, or other techniques for depositing the selected material. The dummy gate layer may then be patterned to form the dummy gates 94 using acceptable photolithography and etching techniques, such as with masks having a pattern of the dummy gates 94. The pattern of the masks is transferred to the dummy gate layer by an acceptable etching technique to form the dummy gates 94.

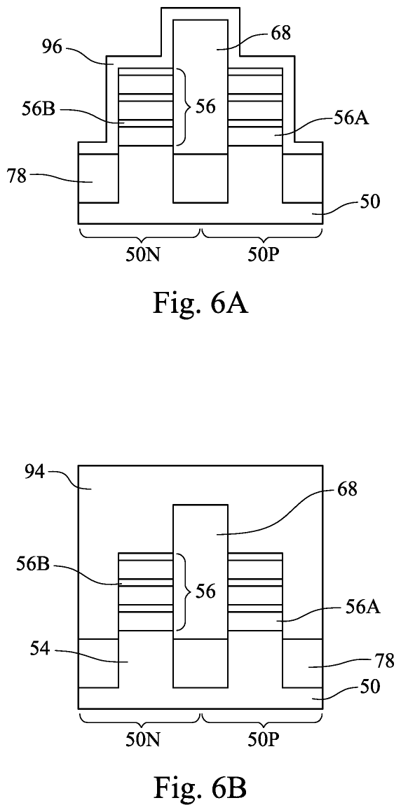

FIG. 6A shows the fin structures 62N and 62P exposed in the intervals between the dummy gates 94, and FIG. 6B shows the fin structures 62N and 62P covered by the dummy gates 94. The fin structures 62N and 62P covered by the dummy gates 94 will be further processed for forming the channel regions in subsequent processes discussed hereinafter. In the illustrated embodiment, a sidewall spacer 96 may be formed over the dielectric wall 68, the fin structures 62N and 62P, and the isolation regions exposed in the intervals between the adjacent dummy gates 94. The sidewall spacer 96 may be conformal to a surface profile of the exposed features between the dummy gates 94.

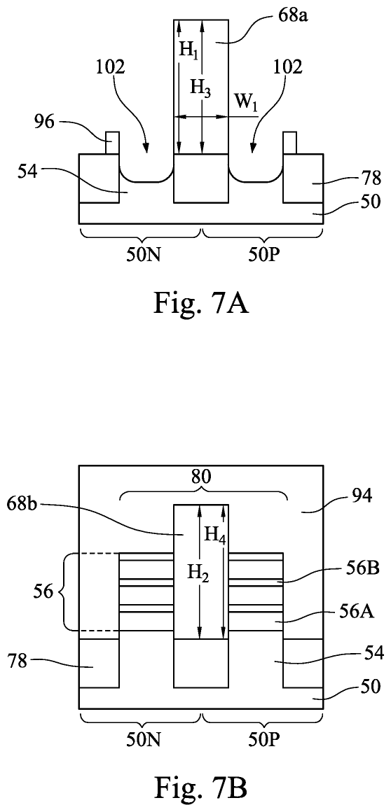

In FIG. 7A, an etching process is performed to remove the exposed fin structures 62N and 62P and portions of the semiconductor fins 54 under the exposed fin structures 62N and 62P. As a result, source/drain recesses 102 are formed in the semiconductor fins 54. An etching process is then performed on the sidewall spacer 96. In the illustrated embodiments, portions of the sidewall spacer 96 remained on the edges of the isolation regions 78 adjacent to the source/drain recesses 102. The etching process for removing the exposed fin structures 62N and 62P includes predominantly an anisotropic etching processing using etching such as a gas mixture of any of HBr, Cl₂, and Ar. After the etching process, the dielectric wall 68 may have a substantially rectangular shape as shown in FIG. 7A. The dielectric wall 68 has a periphery height H₁ at the edge, a central height H₃ at the center, and a width W₁ extending between two opposite sides of the dielectric walls 68. As the dielectric wall 68 is formed with a rectangular shape, the heights H₁ and H₃ are substantially the same, and the width W₁ remains constant from a bottom surface to a top surface of the dielectric wall 68. The relationship between H₁ and H₃ will be discussed further with reference to FIGS. 31(a) and 31(b).

During the etching process for forming the source/drain recesses 102, as shown in FIG. 7B, the forksheet structures 80 are protected from being etched away. The dielectric wall 68 covered by the dummy gate 94, referred to as 68b hereinafter, has a shape similar to the exposed dielectric wall 68 as shown in FIG. 7A, referred to as 68a hereinafter. The heights H₂ at the sidewall and H₄ at the center of the dielectric walls 68b covered by the dummy gates 94 are about the same. As will be described later, subsequent processes will be performed on the protected forksheet structures 80 to form channel regions.

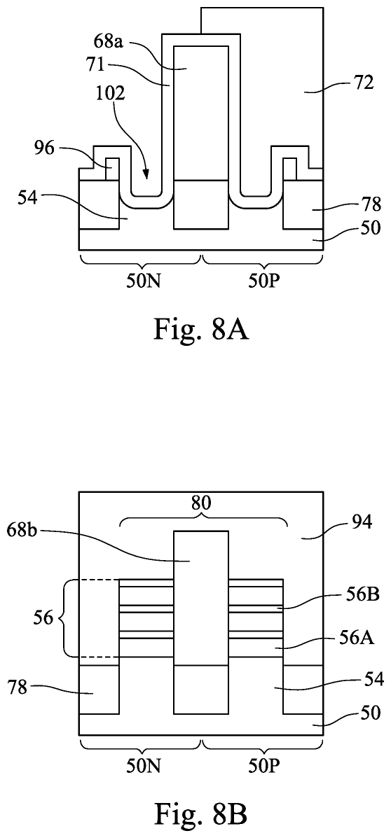

As shown in FIG. 8A, a hard mask 71 is formed along a surface profile of the exposed isolation regions 78, remaining sidewall spacer 96, semiconductor fins 54, and dielectric wall 68a. A photoresist layer 72 is formed to cover hard mask layer 71 in the p-type region 50P and expose the hard mask layer 71 in n-type region 50N. In FIG. 8B, the hard mask layer 71 and the photoresist layer 72 are not formed on the forksheet structures 80 covered by the dummy gate 94 as shown in FIG. 8B.

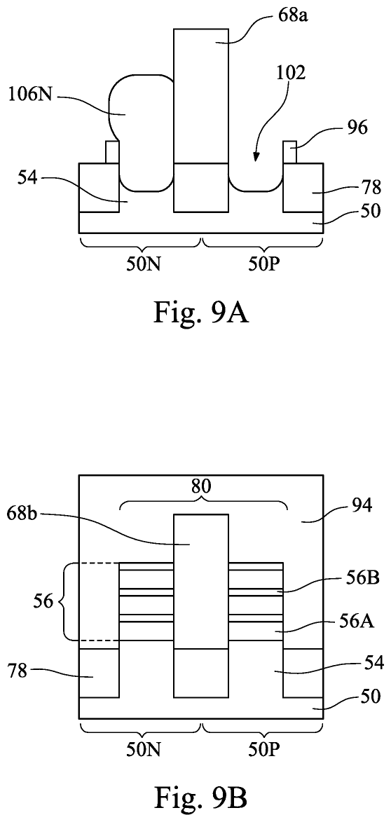

The exposed hard mask layer 71 is then etched to expose the isolation regions 78, the recessed semiconductor fins 54, and a first part of the dielectric wall 68a at the n-type region 50N. Source/drain regions 106N are epitaxially grown from the exposed source/drain recesses 102 in the n-type region 50N as shown in FIG. 9A. The epitaxial source/drain regions 106N may include any acceptable material appropriate for n-type FETs. For example, the epitaxial source/drain regions 106N in the n-type region 50N may include materials such as silicon, silicon carbide, phosphorus doped silicon carbide, silicon phosphide, or the like. The source/drain regions 106N in the n-type region 50N may raise above the remaining sidewall spacer 96 and below the top surface of the dielectric wall 68a. After the source/drain regions 106N are formed in the n-type region 50N, the photoresist layer 72 and the remaining hard mask layer 71 are removed to expose the source/drain recesses 102 in the in the p-type region 50P. During the process for forming the source/drain regions 106N in the n-type region 50N, the forksheet structures 80 covered by the dummy gate 94 is shown in FIG. 9B.

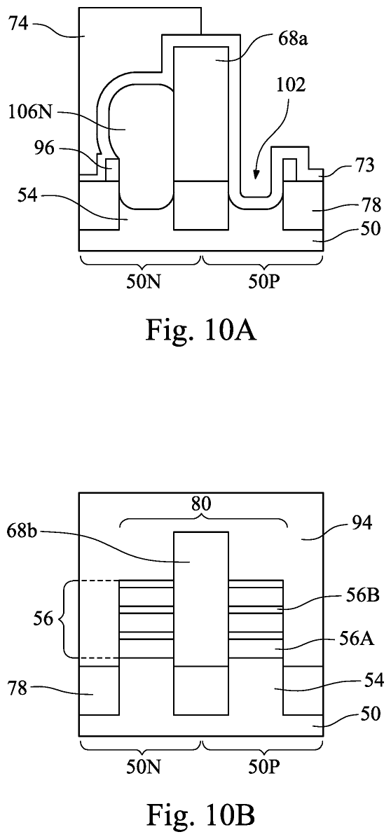

After the photoresist layer 72 is removed, a hard mask layer 73 is formed to cover the exposed surface between the dummy gates 94. As shown in FIG. 10A, the hard mask layer 73 is conformal to the profile of the exposed surface between the adjacent dummy gates 94, including the exposed isolation regions 78, source/drain regions 106N, dielectric wall 68, remaining sidewall spacer 96, and source/drain recesses 102 in the P-type regions 50P. A photoresist layer 74 is formed to cover the n-type region 50N for forming source/drain regions in the p-type region 50P in the subsequent processes. As shown in FIG. 10B, the forksheet structures 80 covered by the dummy gate 94 remain unchanged.

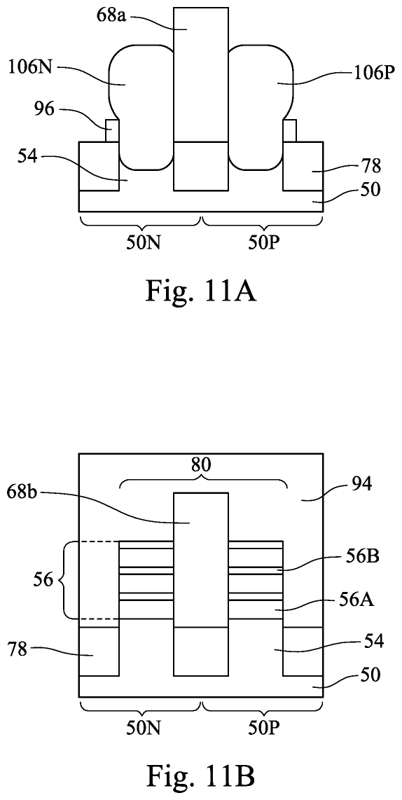

The exposed hard mask layer 73 is then etched with openings to expose the isolation regions 78, the recessed semiconductor fins 54, and the dielectric wall 68 in the p-type region 50P. Epitaxial source/drain regions 106P are grown from the exposed source/drain recesses 102 as shown in FIG. 11A. The epitaxial source/drain regions 106P may include any acceptable material appropriate for p-type FETs. For example, the epitaxial source/drain regions 106P in the p-type region 50P may include materials such as silicon germanium, boron doped silicon germanium, germanium, germanium tin, or the like. The source/drain regions 106P in the p-type region 50P may raise above the remaining sidewall spacer 96 and below the dome shape top of the dielectric wall 68. After the source/drain regions 106P are formed in the p-type region 50P, the photoresist layer 74 is removed. During the process for forming the source/drain regions 106P in the p-type region 50P, the forksheet structures 80 covered by the dummy gate 94 is shown in FIG. 11B.

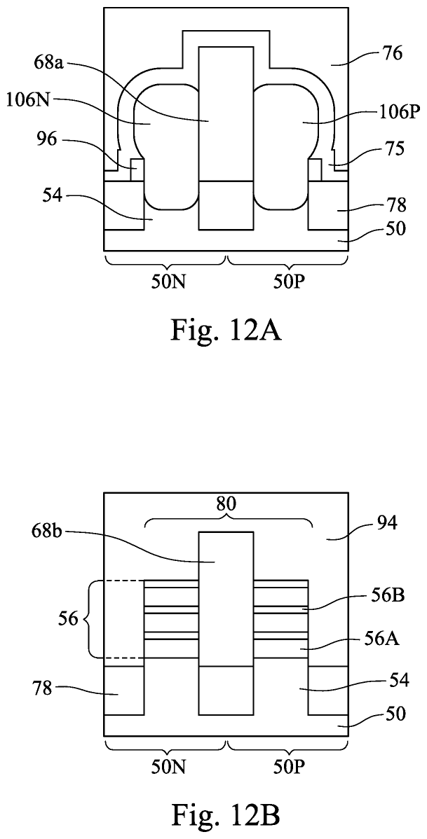

As shown in FIG. 12A, after the source/drain regions 106, including source/drain regions 106N and 106P, are formed in both the n-type region 50N and the p-type regions 50P, respectively, a contact etch stop layer (CESL) 75 is formed over a surface exposed between the dummy gates 94. An interlayer dielectric layer (ILD) 76 is then formed on the contact etch stop layer 75. In the illustrated embodiment, the CESL 75 is conformal to the surface profile of the exposed source/drain regions 106, the dielectric walls 68a, remaining sidewall spacer 96, and isolation regions 78. The CESL 75 may be formed from dielectric materials including silicon nitride, silicon oxide, silicon oxynitride, or the other materials having a high etching selectivity with respect to the ILD 75. FIG. 12B shows the forksheet structure 80 inside of the dummy gate layers 94 during formation of the contact etch stop layer 75 and the ILD layer 76.

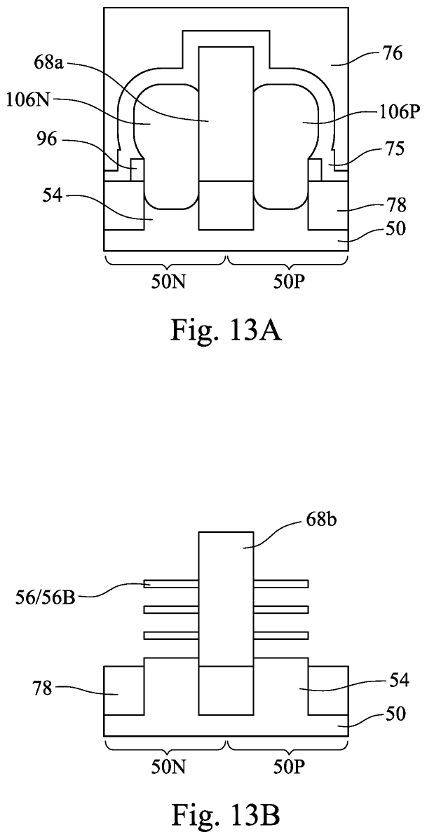

FIG. 13A shows the source/drain regions 106 and the dielectric walls 68a covered with the CESL 74 and the ILD 75 between adjacent dummy gates 94. In FIG. 13B, the dummy gates 94 are removed to expose the nanostructures 56. The dummy gates 94 may be removed by an anisotropic dry etch process. For example, a dry etch process using reaction gases may be used to remove the dummy gates 94. In the illustrated embodiment, the first semiconductors layers 56A in the nanostructures 56 are removed after removal of the dummy gates 94. The second semiconductors layers 56B in the form of stacked nanosheets 56 remained over the semiconductor fins 54 may function as channel regions extending between neighboring source/drain regions 106 and surrounded by the corresponding gates to be formed in the subsequent processes as described later.

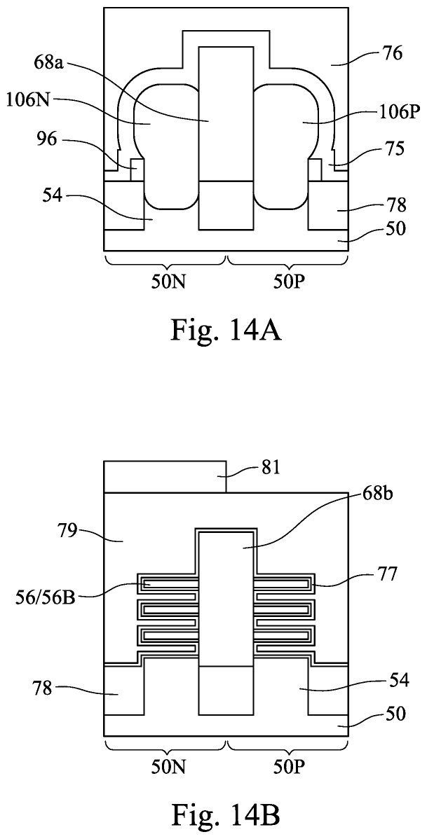

FIG. 14A shows the source/drain regions 106 (106N and 106P) covered with the CESL 75 and the ILD 76 between adjacent nanostructures 56. In FIG. 14B, the surfaces of the nanostructures 56, that is, the stack of second semiconductor layers 56B hanging over the semiconductor fins 54, is covered with a conformal dielectric layer 77. In one embodiment, the gate dielectric layer 77 may be formed from high-k materials such as a silicon oxide layer, a metal oxide layer, a metal silicate layer, or multilayer thereof. The high k-value dielectric layer 77 may function as a gate dielectric layer between the channel regions formed of the nanostructures 56 and gates at in the n-type region 50N and the p-type region 50P in the subsequent processes. A dielectric layer 79 is formed to cover the exposed surfaces of the forksheet structure 80, and a photoresist layer 81 is formed to cover the dielectric layer 79 in the n-type region 50N and expose the dielectric layer 79 for forming the metal gate in the p-type region 50P.

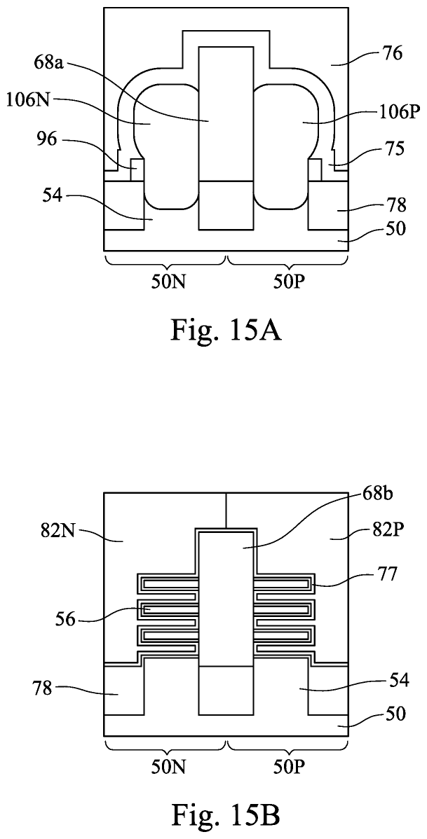

FIG. 15A shows the forksheet structures covered with the CESL 75 and the ILD 76 between adjacent nanostructures 56. After the metal gate 82P in the p-type region 50P is formed, the photoresist layer 81 is removed, and the dielectric layer 79 in the n-type region 50N is removed. A metal gate 82N is formed in the n-type region 50N. As shown in FIG. 15B, the metal gate 82P wrap around the nanostructure 56, that is, the channel regions, in the p-type region 50P and the metal gate 82N wraps around the nanostructures 56, that is, the channel regions, in the n-type region 50N. In one embodiment, the metal gate 82N and the metal gate 82P may physically and electrically in contact with each other. The direct contact may be advantageous when the FETs are used for forming inventors, gates, memories, and the like.

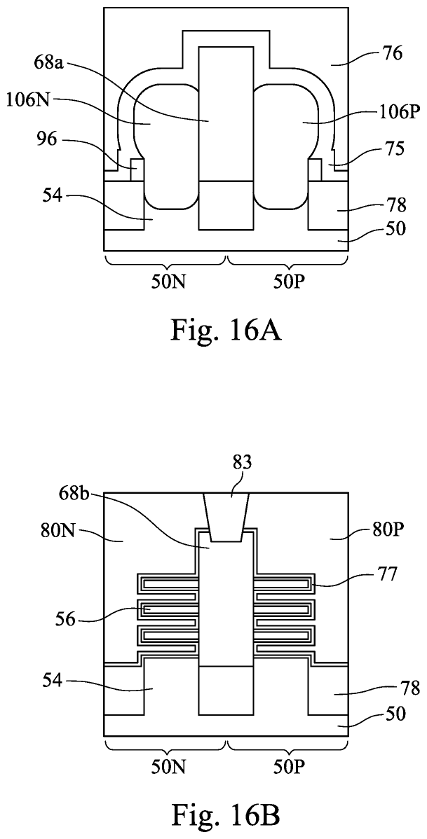

In the Embodiments as show in FIGS. 16A and 16B, an isolation structure 83 is formed on the dielectric wall 68 to isolate the gate 82N in the n-type region 50N from the gate 82P in the p-type region 50P. In FIG. 16A, the source/drain regions 106 isolated by the dielectric walls 68a are covered with the CESL 75 and the ILD 76 between adjacent nanostructures 56. The isolation structure 83 formed in the embodiment as shown in FIG. 16B includes a lower portion extending into the dielectric wall 68b and an upper portion extending above the wall 68b. The dielectric wall 68b and the isolation region 83 provides a complete physical and electric isolation between the gate 82N in the n-type region 50N and the gate 82P in the p-type region 50P.

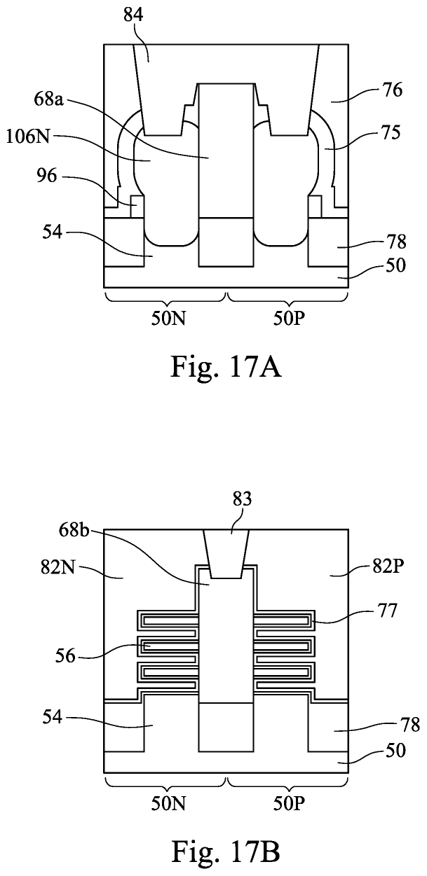

In FIG. 17A, the CESL 75 and the ILD 76 are etched to form openings exposing the portions of underlying dielectric walls 68a and the source/drain regions 106N and 106P. A source/drain (S/D) contact 84 is formed to provide electric connection path for the pair of neighboring source/drain regions 106N and 106P. In the illustrated embodiment, the pair of neighboring source/drain regions 106N and 106P shares a common S/D contact 84. In the forksheet device, the dielectric walls 68b need to be high enough for work function metal (WFM) patterning, for example, for gate patterning processes, and for providing effective isolation between the source/drain regions 106N and 106P. The shallow space for forming the S/D contact 84 and the significant height of the dielectric walls 68a inevitably degrades the contact resistance (R_{C}) between the contact 84 and the source/drain regions 106 due to the sidewall shadowing of CESL 75 formed along sidewalls of the dielectric walls 68a. In the illustrated embodiment, the sidewall shadow of the CESL 75 results in incomplete etching of the CESL 75 along the sidewall of the dielectric wall 68. Therefore, the contact area between the S/D contact 84 and the source/drain regions 106 are reduced, and the resistance R_{C} is increased.

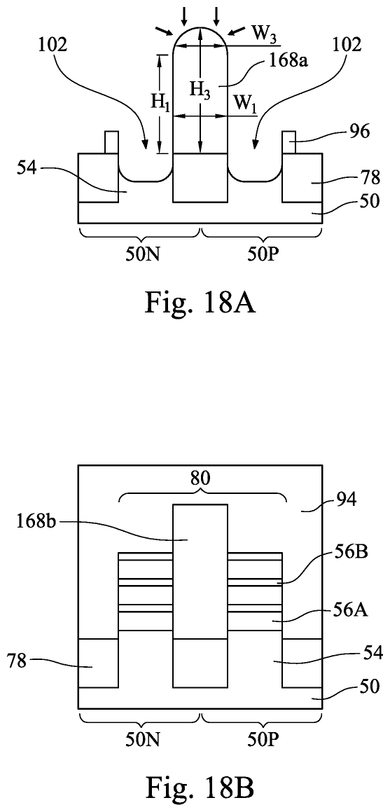

FIGS. 18A-B through 29A-B are cross-sectional views of intermediate stages in the manufacturing of forksheet FETs in accordance with another embodiment. FIGS. 18A and 18B are performed after the processes as shown in FIGS. 2A to 6B have been performed. In FIGS. 18A-B through 29A-B, figures ending with an “A” designation are illustrated along the reference cross-section A-A illustrated in FIG. 1 and figures ending with a “B” designation are illustrated along the reference cross-section B-B illustrated in FIG. 1.

In FIG. 18A, an etching process is performed to remove the exposed fin structures 62N and 62P and portions of the semiconductor fins 54 under the exposed fin structures 62N and 62P. As a result, source/drain recesses 102 are formed in the semiconductor fins 54. The sidewall spacer 96 is then etched. In the illustrated embodiments, portions of the sidewall spacer 96 remained on the edges of the isolation regions 78 adjacent to the source/drain recesses 102. The etching process for removing the exposed fin structures 62N and 62P includes predominantly, for example, an anisotropic etching processing using etching such as a gas mixture of any of HBr, Cl₂, and Ar. However, instead of forming the dielectric wall 168a with a rectangular shape as the dielectric wall 68a as shown in FIG. 7A, the etching parameters and/or conditions are controlled to form the electric wall 168a with a rounded top portion, for example, a dome shape top portion. The dome shape top portion may also be obtained by selecting a suitable material for forming the dielectric layer 66 in the process as shown in FIG. 3. For example, the dielectric layer 66 may be formed using SiN or other similar materials. As shown from FIG. 18A, the lower portion of the dielectric wall 168 has a width W₁ similar to the width W₁ of the rectangular dielectric wall 68 as shown in FIG. 7A. However, the dome shape top portion has a gradually decreased width W₃ from a point where the dielectric wall 168a is in direct contact with a top surface of source/drain regions to be formed subsequently towards a tip or apex of the dielectric wall 168a. Therefore, the height H₁ at the edge of the dielectric wall 168a is shorter than the height H₃ of the central portion of the dielectric wall 168a.

During the etching process for forming the source/drain recesses 102, as shown in FIG. 18B, the forksheet structures 80 are protected from being etched away. As will be described later, subsequent processes will be performed on the protected forksheet structures 80 to form channel regions.

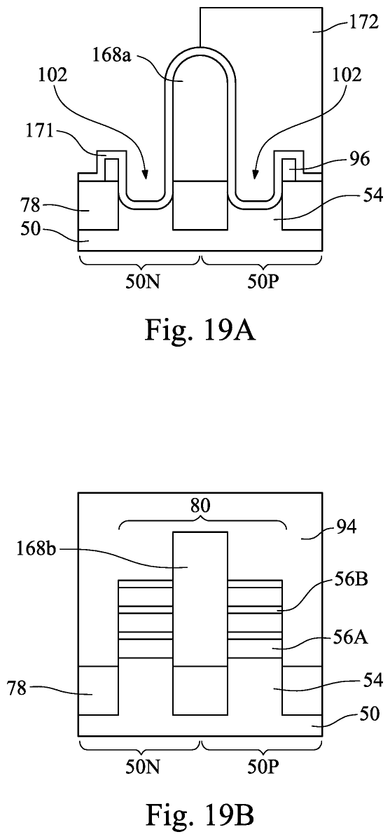

In FIG. 19A, a hard mask 171 is formed along a surface profile of the exposed isolation regions 78, remaining sidewall spacer 96, semiconductor fins 54, and the dielectric wall 168a. A photoresist layer 172 is formed over hard mask layer 171 in the p-type region 50P. In the illustrated embodiment, the wall 168a adjacent to the semiconductor fin 54 in the n-type region 50N, the remaining sidewall spacer layer 96, and the isolation regions 78 are covered by the photoresist layer 172. In FIG. 19B, the hard mask layer 171 and the photoresist layer 172 are not formed on the forksheet structures 80 covered by the dummy gate 94.

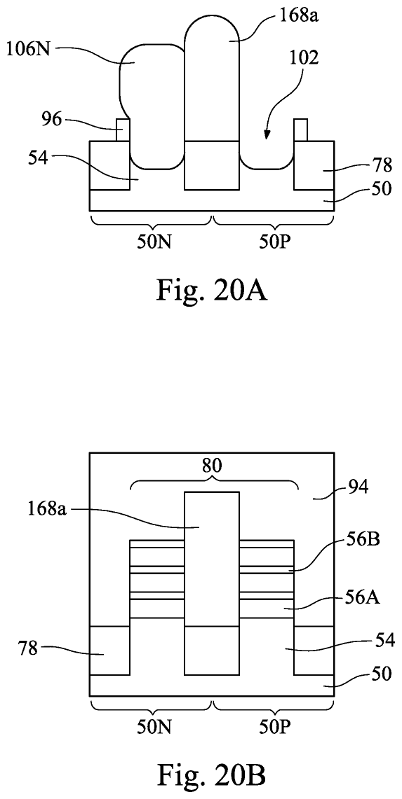

The exposed hard mask layer 171 is then etched to expose the isolation regions 78, the recessed semiconductor fins 54, and a first part of the dielectric wall 168 at the n-type region 50N. Epitaxial source/drain regions 106 are grown from the exposed source/drain recesses 102 as shown in FIG. 20A. The epitaxial source/drain regions 106 may include any acceptable material appropriate for n-type FETs. For example, the epitaxial source/drain regions 106 in the n-type region 50N may include materials such as silicon, silicon carbide, phosphorus doped silicon carbide, silicon phosphide, or the like. The source/drain regions 106 in the n-type region 50N may raise above the remaining sidewall spacer 96 and below the dome shape top of the dielectric wall 168. After the source/drain regions 106 are formed in the n-type region 50N, the photoresist layer 172 is removed to expose the source/drain recesses 102 in the in the p-type recesses 102. During the process for forming the source/drain regions 106 in the n-type region 50N, the forksheet structures 80 covered by the dummy gate 94 is shown in FIG. 20B.

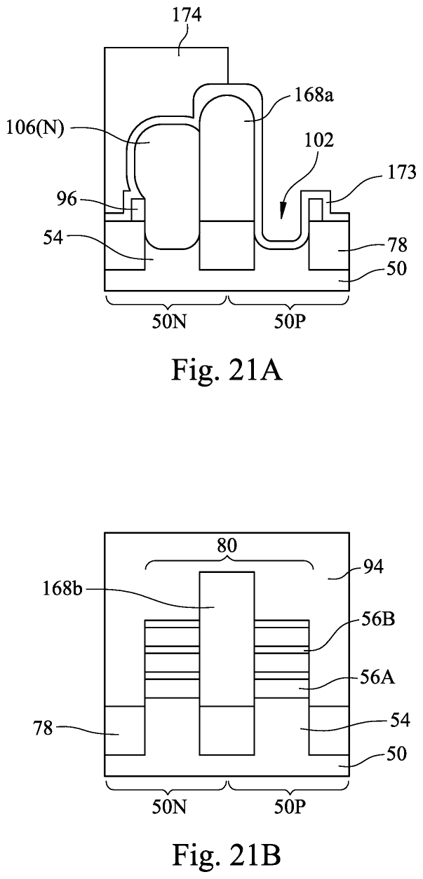

After the photoresist layer 172 is removed, a hard mask layer 173 is formed to over a surface uncovered by the dummy gate 94. As shown in FIG. 21A, the hard mask layer 173 is conformal to the surface profile of the exposed area, including the exposed isolation regions 78, source/drain regions 106, dielectric wall 168a, remaining sidewall spacer 96, and source/drain recesses 102. A photoresist layer 174 is formed to cover the n-type region 50N for forming source/drain regions in the p-type region 50P in the subsequent processes. As shown in FIG. 21B, the forksheet structures 80 covered by the dummy gate 94 remain unchanged.

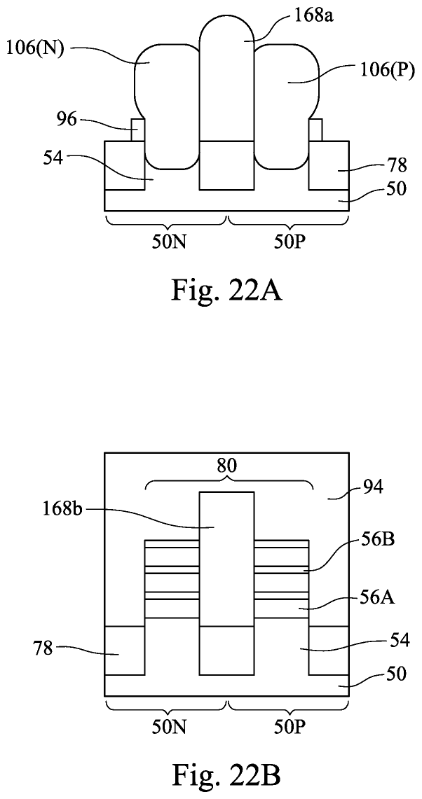

The exposed hard mask layer 173 is then etched to expose the isolation regions 78, the recessed semiconductor fins 54, and the dielectric wall 68 at the p-type region 50P. Source/drain regions 106P are epitaxially grown from the exposed source/drain recesses 102 as shown in FIG. 22A. The epitaxial source/drain regions 106P may include any acceptable material appropriate for p-type FETs. For example, the epitaxial source/drain regions 106P in the p-type region 50P may include materials such as silicon germanium, boron doped silicon germanium, germanium, germanium tin or the like. The source/drain regions 106 in the p-type region 50P may raise above the remaining sidewall spacer 96 and below the dome shape top of the wall 168a. After the source/drain regions 106 are formed in the p-type region 50P, the photoresist layer 174 is removed. During the process for forming the source/drain regions 106 in the n-type region 50N, the forksheet structures 80 covered by the dummy gate 94 is shown in FIG. 22B.

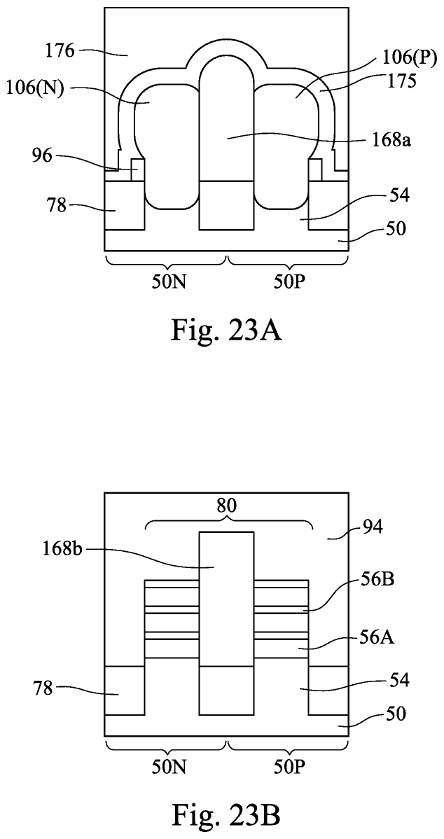

As shown in FIG. 23A, after the source/drain regions 106 have been formed in both the n-type region 50N and the p-type regions 50P, a contact etch stop layer (CESL) 175 is formed over surfaces exposed between and uncovered by the dummy gates 94. An interlayer dielectric layer (ILD) 176 is then formed on the contact etch stop layer (CESL) 175. In the illustrated embodiment, the CESL 175 is conformal to the surface profile of the exposed surfaces. The CESL 175 may be formed from dielectric materials including silicon nitride, silicon oxide, silicon oxynitride, or the other materials having a high etching selectivity with respect to the ILD 175. FIG. 23B shows the forksheet structure 80 inside of the dummy gate layers 94 during formation of the contact etch stop layer 175 and the ILD layer 176.

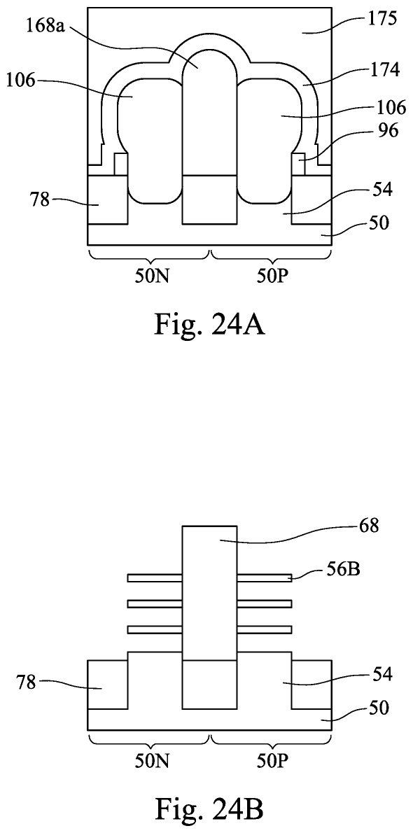

FIG. 24A shows the structures covered with the CESL 175 and the ILD 176 between adjacent dummy gates 94. As shown in FIG. 24B, the dummy gates 94 are removed to expose the nanostructures 56. The dummy gates 94 may be removed by an anisotropic dry etch process. For example, a dry etch process using reaction gases may be used to remove the dummy gates 94. In the illustrated embodiment, the first semiconductors layers 56A in the nanostructures 56 are removed after removal of the dummy gates 94. The second semiconductors layers 56B remained over the semiconductor fins 54 may function as channel regions disposed between neighboring source/drain regions 106.

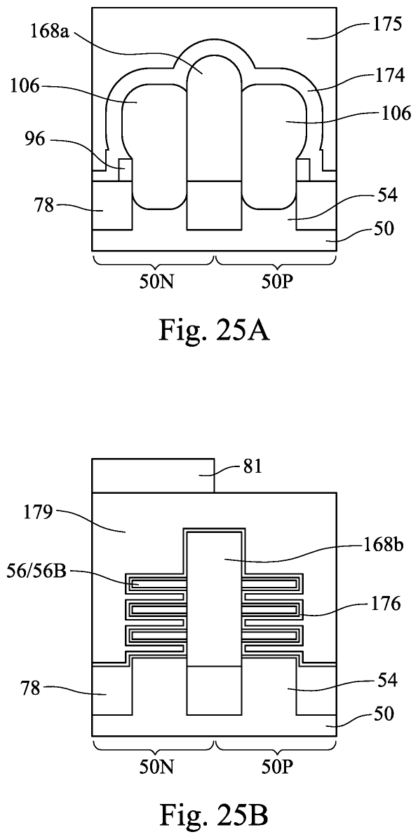

FIG. 25A shows the structures covered with the CESL 175 and the ILD 176 between adjacent nanostructures (nanosheet) 56 that includes the stack of second semiconductor layers 56B hanging over the substrate 50. In FIG. 25B, the exposed surfaces of the nanostructures 56 is covered with a high k-value dielectric layer 176. In one embodiment, the gate dielectric layer 176 may be formed conformal to the nanostructures 56 and using high-k materials such as a silicon oxide layer, a metal oxide layer, a metal silicate layer, or a multilayer made thereof. The high k-value dielectric layer 176 may function as a gate dielectric layer between the channel regions formed of the nanostructures 56 and gates (82N and 82P) at in the n-type region and the n-type region in the subsequent processes. A dielectric layer 179 is formed to cover the exposed surfaces of the forksheet structure 80, and a photoresist layer 81 is formed to cover the dielectric layer 179 and expose the dielectric layer 179 for forming the metal gate in the p-type region 50P.

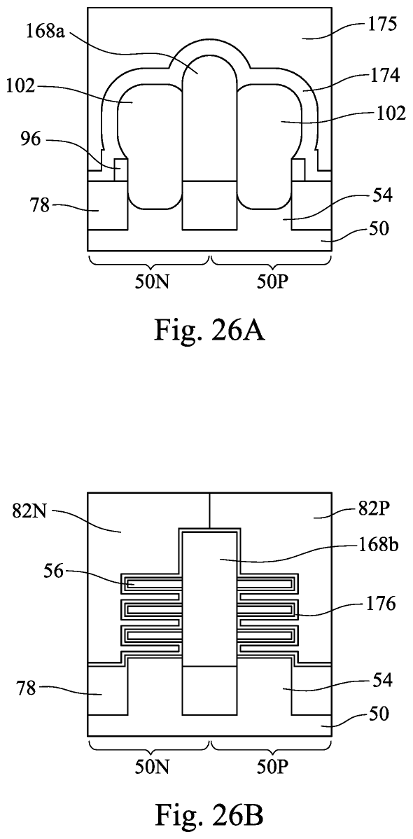

FIG. 26A shows the structures covered with the CESL 175 and the ILD 176 between adjacent nanostructures 56. After the metal gate 82P in the p-type region 50P is formed, the photoresist layer 81 is removed, and the dielectric layer 79 in the n-type region 50N is removed. A metal gate 82N is formed in the n-type region 50N. In FIG. 26B, the metal gate 82P wraps around the nanostructure 56 in the p-type region 50P and a metal gate 82N wraps around the nanostructures 56 in the n-type region 50N. In the configuration as shown in FIG. 26B, the metal gate 82N and the metal gate 82P may physically and electrically in contact with each other. The direct contact may be advantageous when the FETs are used for forming inventors, gates, memories, and the like.

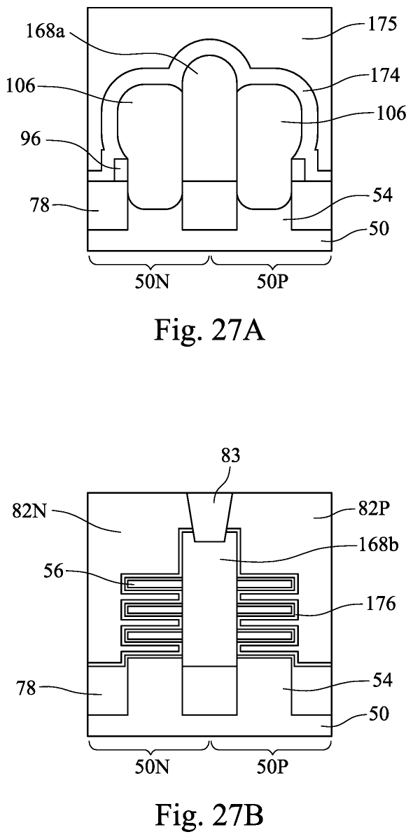

In the Embodiments as shown in FIGS. 27A and 27B, an isolation structure is formed on the dielectric wall 168b to isolate the gate 82N in the n-type region 50N from the gate 82P in the p-type region 50P. In FIG. 27A, the forksheet structures is covered with the CESL 175 and the ILD 175 between adjacent nanostructures 56. As shown in FIG. 27B, an isolation structure 83 is formed with a bottom portion extending into the dielectric wall 168b, and an upper portion extending above the dielectric wall 168b to isolate the gate 82N in the n-type region 50N from the gate 82P in the p-type region 50P. Similar to the isolation structure 83 formed in the embodiment as shown in FIG. 16B, a lower portion of the isolation structure 83 extends into the dielectric wall 168b and an upper portion extending above the dielectric wall 168b. The dielectric wall 168b and the isolation region 83 provides a complete physical and electric isolation between the gate 82N in the n-type region 50N and the gate 82P in the p-type region 50P.

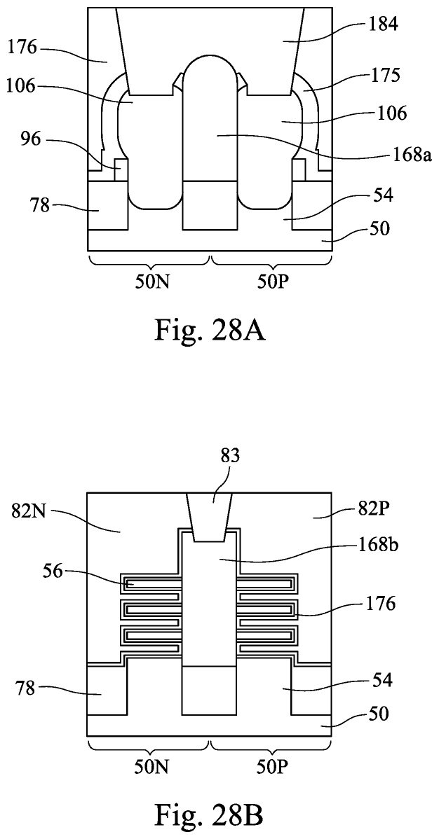

In FIGS. 28A and 28B, the CESL 175 and the ILD 176 are etched to form openings exposing the portions of underlying dielectric walls 168 and the source/drain regions 106N and 106P. A source/drain (S/D) contact 184 is formed to provide electric connection path for the pair of neighboring source/drain regions 106N and 106P. In the illustrated embodiment, the pair of neighboring source/drain regions 106N and 106P shares a common S/D contact 184. As the CESL layer 175 is formed conformal to the surface profile of the source/drain regions 106 and the dielectric wall 168a, the CESL layer 175 is curved at the top portion of the dielectric wall 168a instead of an upright straight CESL layer 75 on the sidewall of the dielectric wall 68 as shown in FIG. 16A.

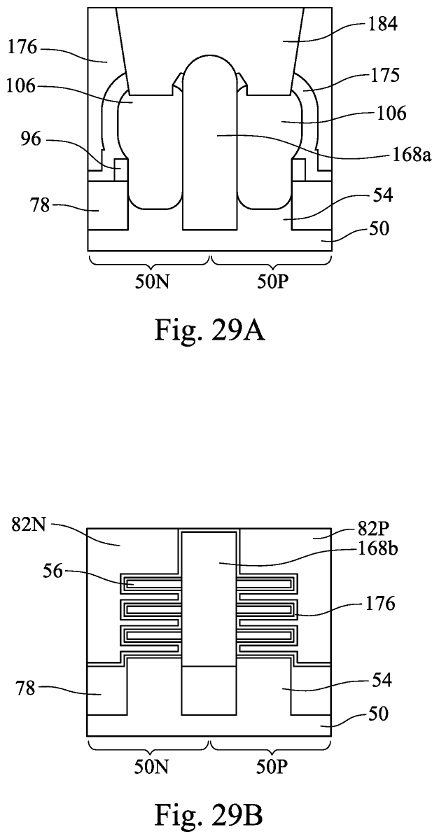

In another embodiment as shown in FIG. 29A, the dielectric wall 168a may be formed into the isolation region 78 or to extend through the isolation region 78 towards the substrate 50. To form the dielectric wall 168a as shown in FIG. 29A, in the step as shown in FIG. 2, the isolation region 78 between the pair of fin structures 62N and 62P may be partially or completely removed before forming the dielectric layer 66 in FIG. 3. Therefore, the sidewall shadowing effect of the etching process occurring to FIG. 16A is either minimized or eliminated. Therefore, as shown in FIG. 29A, the CESL 175 remaining between the S/D contacts 184, the dielectric wall 168a, and the source/drain regions 106 is insignificant or completely removed. As a result, contact area of the S/D contact 184 is increased, and the resistance R_{C} between the S/D contacts 184 and the source/drain regions 106 is increased.

In some embodiments, the metal gates 82N and 82P may be polished, for example, by chemical mechanical polishing (CMP), to level with a top surface of the gate dielectric layer 176 as shown in FIG. 29B. Consequently, a portion of the ILD 176 may be removed. Alternatively, the CMP may be performed until the metal gates 82N and 82P are lower than a top surface of the dielectric wall 168b. In this situation, the isolation region 83 is thus unnecessary in this embodiment. The CMP process may also remove a portion of the ILD layer 176. In some embodiments, a portion of the hard mask layer 175, or even a portion of the dielectric wall 168a, may be removed by the CMP process to expose the dielectric wall 168b. In some embodiment, the top portion of the dielectric wall 168b may be formed with similar shape as the top portion of the dielectric wall 168b.

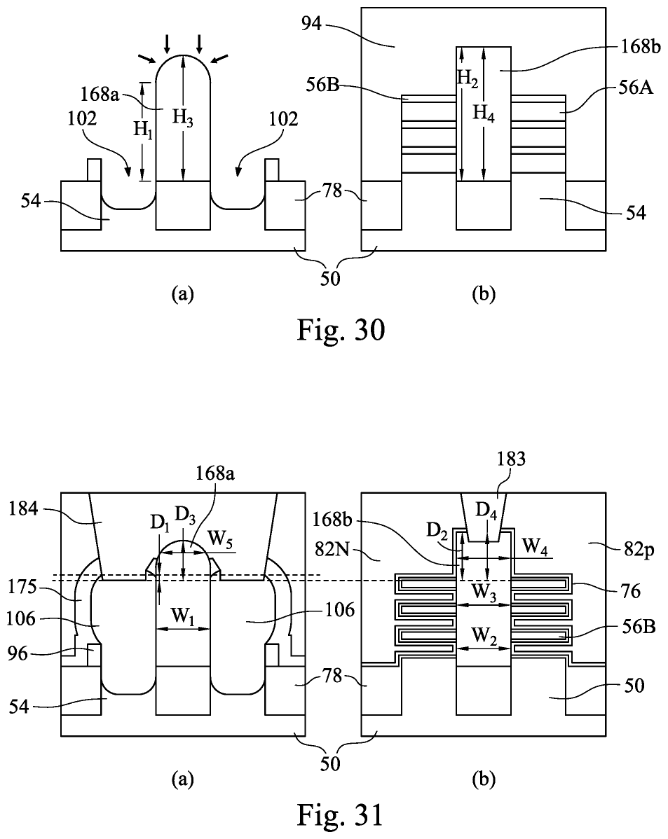

In one embodiment, the dielectric wall 168a in FIG. 18A to 29B may be formed with a central height H₃ lower than the central height H₃ in the rectangular dielectric wall 68a as shown in FIG. 7A. This creates more space in the depth direction for forming the S/D contacts 184, such that the contact resistance R_{C} may be further reduced. For example, in one embodiment as shown in FIGS. 30(a) and 30(b), the central height H₃ of the dielectric wall 168a between the source/drain recesses 102 is shorter than the height H₄ of the dielectric wall 168b covered inside of the dummy gate 94. With the shorter dielectric wall 168a, more space is allowed for forming the S/D contacts 184, while the sufficient height of the dielectric wall 168b is maintained for isolation of the WFM 82P and 82N. In the illustrated embodiments, the central height H₃ is about 4 nm to about 55 nm shorter than the height H₂ and H₄ at both the edge and the center of the dielectric wall 168b. The edge height, that is, the height H₁ along the side edge of the dielectric 168b is about 0 nm to about 50 nm smaller than the heights H₂ and H₄. In the subsequent processes, the S/D contacts 184 extending across the dielectric wall 168a is formed as shown in FIG. 31(a), and metal gates 82N, 82P, and the isolation region 183 are formed as shown in FIG. 31(b). In FIGS. 31(a) and 31(b), D₁ and D₂ are the height of the top portion at the edges of the dielectric wall 168a and 168b, respectively, and D₃ and D₄ are the height of the top portion at the center of the dielectric wall 168a and 168b, respectively. D₄ may be within a range of about 10 nm to about 55 nm. As the dielectric wall 168a is formed with a convex or dome shape, D₃>D₁, and D₃-D₁ is larger than D₄-D₂ by about 0 nm to about 20 nm.

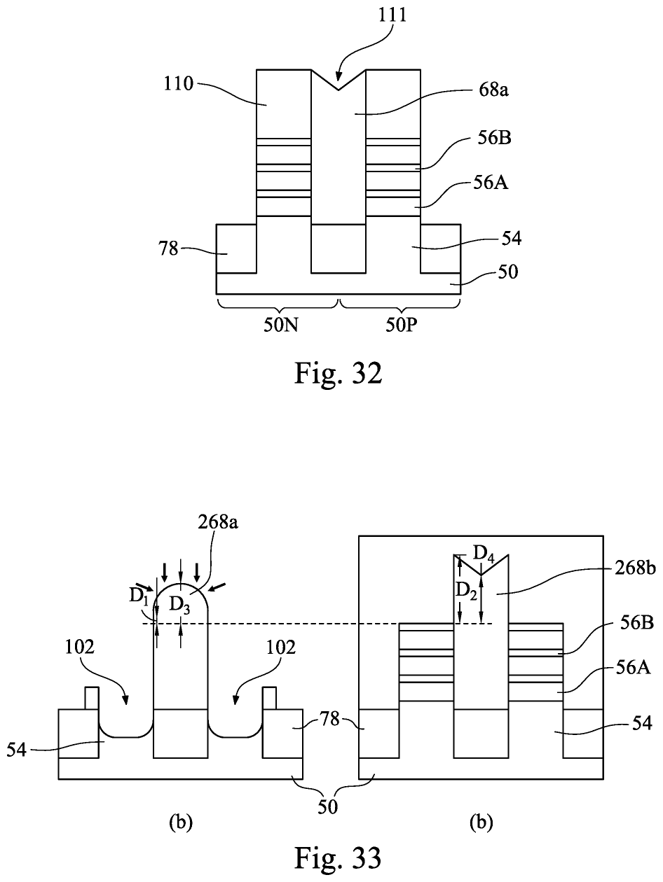

In the embodiment as shown in FIGS. 31 to 32, W₁ is the width of the lower portion of the dielectric wall 168a, W₂ is the width of the dielectric wall 168b between the nanosheets, that is, the channel regions 56B, W₃ is the width of the dielectric wall 168b between the metal gates 82N and 82P, W₄ is the width of the dielectric wall 168b at the top portion above the nanosheets 56B, and W₅ is the width of the dielectric wall 168a at the dome shape top. W₁ is smaller than W₂ within a range of about 2 nm to about 16 nm. W₂ is larger than W₃ within a range of 2 nm to about 10 nm. W₄ is smaller than W₂ for about 2 nm to about 10 nm. W₅ is smaller than W₁ within a range of about 2 nm to about 10 nm.

In some embodiment, a notch 111 may be formed at the top surface of the dielectric wall 68 as shown in FIG. 5A. The notch 111 may be formed by performing etching, for example, anisotropic etching, on the exposed dielectric wall 68 using a mask layer 110 covering the nanostructures 56 adjacent to the dielectric wall 68 as shown in FIG. 32. In some embodiment, the notch 111 may also be formed in the dielectric wall 68 between the fin structures 62N and 62P predetermined for forming the channel regions before forming the dummy gates 94 as shown in FIG. 5B. In the subsequent processes for forming the source/drain recesses 102, the dielectric wall 268a is formed with a smooth or rounded top portion with a reduced overall height, while the dielectric wall 268b covered with the dummy gates 94 may have a groove recessed from the top surface as shown in FIGS. 33(a) and 33(b). As shown in FIG. 33(b), the notch 111 formed in the dielectric wall 268b provides more landing area for the isolation region 83 without reducing the height H₂ for appropriate isolation between the metal gates 82N and 82P. In the illustrated embodiment, D₃>D₁ and D₄<D₂.

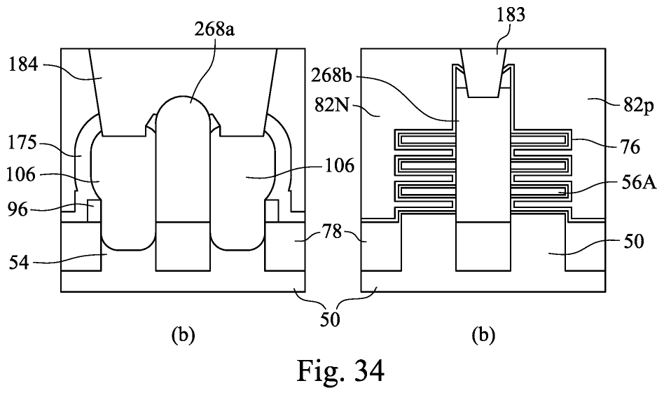

In the subsequent processes for forming the source/drain recesses 102, the dielectric wall 268a is formed with a smooth or rounded top portion with a reduced overall height, while the dielectric wall 268b covered with the dummy gates 94 may have a groove recessed from the top surface as shown in FIGS. 34(a) and 34(b). In the illustrated embodiments, the dielectric wall 268a is formed from a structure on which a notch 111 is formed. The notch 111 is also formed in the dielectric wall 268b to provide more landing area for the isolation region 83 without reducing the height H₂ for appropriate isolation between the metal gates 82N and 82P.

In one embodiment, a semiconductor device structure is provided. The semiconductor device has a first dielectric wall between an n-type source/drain region and a p-type source/drain region to isolate the n-type source physically and electrically/drain region and the p-type source/drain region from each other. A second dielectric wall is formed between a first channel region connected to the n-type source/drain region and a second channel region connected to the p-type source/drain region. A contact is formed to physically and electrically connect the n-type source/drain region with the p-type source/drain region, wherein the contact extends over the first dielectric wall. The first electric wall has a gradually decreasing width W₅ toward a tip of the first dielectric layer from a top contact position of between the first dielectric wall and either the n-type source/drain region or the p-type source/drain region.

The semiconductor device may further comprise a first metal gate wrapping the first channel region therein in the n-type region and a second metal gate wrapping the second channel region therein in the p-type region. A gate isolation region may be formed to extend from the second dielectric wall to physically and electrically isolate the first and second metal gates. In some embodiments, the first metal gate and the second metal gate may have top surfaces level with a top surface of the second dielectric wall. The second dielectric wall may have a width W₂ between the first and second channel regions smaller than a width W₃ between the first and second metal gates filling between nanosheets of the first and second channel regions. The first dielectric wall may have a width W₁ below the top contact position smaller than a width W₃ between the first and second metal gates filling between adjacent nanosheets of the first and second channel regions by about 2 nm to about 6 nm. In one embodiment, W₂ may be smaller than W₃ within a range of about 2 nm to about 16 nm. The second dielectric wall may have a width W₄ above a top surface of the first and second channel regions smaller than a width W₂ between the first and second metal gates filling between adjacent nanosheets by about 2 nm to about 10 nm.

The semiconductor device may further comprise a shallow trench isolation region (STI) formed between the n-type region and the p-type region in the substrate, and the first dielectric wall may be formed on the STI. In one embodiment, each of the first and second channel region may include a stack of conductive nanosheets over the n-type region and the p-type region, respectively. The first dielectric wall may have a width W₁ at a level below the top contact positions smaller than a width W₂ of the second dielectric wall between the metal gates. The first dielectric wall is more convex than the second dielectric wall. A distance between a tip of the first dielectric wall and the top contact position is shorter than a distance between a top surface of the second dielectric wall and a top surface of the first or second channel regions by about 0 nm to about 20 nm. A distance between a top surface of the first and second channel regions to a top surface of the second dielectric wall is about 10 nm to about 55 nm. The first dielectric wall may be made of a material different from a material of the second dielectric wall.

A device is provided in another embodiment. The device includes a substrate. A plurality of n-type semiconductor strips and a plurality of p-type semiconductor strips are formed in the substrate. The p-type semiconductor strips extend in parallel with the n-type semiconductor strips. A plurality of shallow trench isolation regions (STI) is formed between each pair of immediately adjacent n-type semiconductor strips and p-type semiconductor strips. A series of channel regions is periodically formed on each of the n-type semiconductor strips and each of the p-type semiconductor strips, and an n-type source/drain region is formed in each interval between each pair of adjacent channel regions in the n-type semiconductor strips and a p-type source/drain region formed in each interval between each pair of adjacent channel regions in the p-type semiconductor strips. A first dielectric wall is formed between each pair of immediately adjacent n-type source drain region and p-type source/drain region. The first dielectric wall has a height gradually decreasing from a center to a periphery thereof. A second dielectric wall is formed between each pair of immediately adjacent channel regions.

A method of forming a device is provided. The method includes steps of forming a first dielectric wall and a second dielectric wall each having a notch recessed from a top surface thereof; forming a source/drain region at each of two opposite sides of the first dielectric wall and etching the first dielectric wall to be shorter than the second dielectric wall and rounding a top portion of the first dielectric wall; forming a pair of channel regions each including a stack of nanosheets extending away from two opposite sidewalls of the second dielectric wall; and forming a pair of metal gates at two opposite side of the second dielectric wall, the metal gates filling spaces between adjacent nanosheets of each of the channel regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first dielectric wall between an n-type source/drain region and a p-type source/drain region to physically and electrically isolate the n-type source/drain region and the p-type source/drain region from each other;
a second dielectric wall between a first channel region connected to the n-type source/drain region and a second channel region connected to the p-type source/drain region; and
a contact formed to physically and electrically connect the n-type source/drain region with the p-type source/drain region, wherein the contact extends over the first dielectric wall,
wherein the first dielectric wall has a gradually decreasing width W₅ towards a tip of the dielectric wall from a top contact position between the first dielectric wall and either the n-type source/drain region or the p-type source/drain region.

2. The semiconductor device of claim 1, further comprising a substrate having an n-type region and a p-type region extending in parallel to each other, wherein
the n-type source/drain region and the first channel region are formed side-by-side to each other in the n-type region; and
the p-type source/drain region and the second channel region are formed side-by-side to each other in the p-type region.

3. The semiconductor device of claim 2, further comprising a first metal gate wrapping the first channel region therein in the n-type region and a second metal gate wrapping the second channel region therein in the p-type region.

4. The semiconductor device of claim 3, further comprising a gate isolation region extending from the second dielectric wall to physically and electrically isolate the first and second metal gates.

5. The semiconductor device of claim 3, wherein the first metal gate and the second metal gate have top surfaces level with a top surface of the second dielectric wall.

6. The semiconductor device of claim 3, wherein the second dielectric wall has a width W₂ between the first and second channel regions smaller than a width W₃ between the first and second metal gates filling between nanosheets of the first and second channel regions.

7. The semiconductor device of claim 6, wherein the first dielectric wall has a width W₁ below the top contact position smaller than a width W₃ between the first and second metal gates filling between adjacent nanosheets of the first and second channel regions by about 2 nm to about 6 nm.

8. The semiconductor device of claim 7, wherein W₂ is smaller than W₃ within a range of about 2 nm to about 16 nm.

9. The semiconductor device of claim 6, wherein the second dielectric wall has a width W₄ above a top surface of the first and second channel regions smaller than a width W₂ between the first and second metal gates filling between adjacent nanosheets by about 2 nm to about 10 nm.

10. The semiconductor device of claim 2, wherein the substrate further comprising a shallow trench isolation region (STI) between the n-type region and the p-type region, and the first dielectric wall is formed on the STI.

11. The semiconductor device of claim 2, each of the first and second channel region includes a stack of conductive nanosheets over the n-type region and the p-type region, respectively.

12. The semiconductor device of claim 1, wherein the first dielectric wall has a width W₁ at a level below the top contact positions smaller than a width W₂ of the second dielectric wall between the metal gates.

13. The semiconductor device of claim 1, wherein the first dielectric wall is more convex than the second dielectric wall.

14. The semiconductor device of claim 1, wherein a distance between a tip of the first dielectric wall and the top contact position is shorter than a distance between a top surface of the second dielectric wall and a top surface of the first or second channel regions by about 0 nm to about 20 nm.

15. The semiconductor device of claim 1, wherein a distance between a top surface of the first and second channel regions to a top surface of the second dielectric wall is about 10 nm to about 55 nm.

16. The semiconductor device of claim 1, wherein the first dielectric wall may be made of a material different from a material of the second dielectric wall.

17. A device, comprising:
a substrate;
a plurality of n-type semiconductor strips formed in the substrate;
a plurality of p-type semiconductor strips formed in the substrate, the p-type semiconductor strips extending in parallel with the n-type semiconductor strips;
a plurality of shallow trench isolation regions (STI) between each pair of immediately adjacent n-type region and p-type region;
a series of channel regions periodically formed on each of the n-type semiconductor strips and each of the p-type semiconductor strips;
an n-type source/drain region formed in each interval between each pair of adjacent channel regions in the n-type semiconductor strips and a p-type source/drain region formed in each interval between each pair of adjacent channel regions in the p-type semiconductor strips;
a first dielectric wall formed between each pair of immediately adjacent n-type source/drain region and p-type source/drain region, wherein the first dielectric wall has a height gradually decreasing from a center to a periphery thereof; and
a second dielectric wall formed between each pair of immediately adjacent channel regions.

18. The device of claim 17, wherein the first dielectric wall has a height lower than a height of the second dielectric wall.

19. The device of claim 18, wherein the second dielectric wall has a notch recessed from a top surface thereof.

20. A method of forming a device, comprising:
forming a first dielectric wall and a second dielectric wall each with a notch recessed from a top surface thereof;
forming a source/drain region at each of two opposite sides of the first dielectric wall and etching the first dielectric wall to be shorter than the second dielectric wall and rounding a top portion of the first dielectric wall;
forming a pair of channel regions each including a stack of nanosheets extending away from two opposite sides of the second dielectric wall; and
forming a pair of metal gates at the two opposite sides of the second dielectric wall, the metal gates filling spaces between adjacent nanosheets of each of the channel regions.
